(19) United States
(12) Patent Application Publication
(10) Pub. No.: US 2017/0093501 A1
(43) Pub. Date: Mar. 30, 2017

(54) MINIATURIZED DEVICES FOR COMBINED OPTICAL POWER CONVERSION AND DATA TRANSMISSION

(71) Applicant: Semprius, Inc., Durham, NC (US)

(72) Inventors: Matthew Meitl, Durham, NC (US); Scott Burroughs, Raleigh, NC (US); Brent Fisher, Durham, NC (US); Brian Cox, Durham, NC (US); Joseph Carr, Chapel Hill, NC (US)

(21) Appl. No.: 15/280,627

(22) Filed: Sep. 29, 2016

Related U.S. Application Data
(60) Provisional application No. 62/234,302, filed on Sep. 29, 2015.

(51) Int. Cl. H04B 10/60; H01L 31/043

(52) U.S. Cl. CPC H04B 10/60; H01L 31/043

(57) ABSTRACT

An optical data communication and power converter device includes a receiver circuit comprising an optical receiver. The optical receiver includes a photovoltaic device and a photoconductive device arranged within an area that is configured for illumination by a modulated optical signal emitted from a monochromatic light source of a transmitter circuit. The photovoltaic device is configured to generate electric current responsive to the illumination of the area by the modulated optical signal. The photoconductive device is configured to generate a data signal, distinct from the electric current, responsive to the illumination of the area by the modulated optical signal. A reverse bias voltage may be applied to the photoconductive device by the photovoltaic device, independent of an external voltage source. Related devices and methods of operation are also discussed.

### CLAIM OF PRIORITY

This application claims priority from U.S. Provisional Patent Application Ser. No. 62/234,302 entitled “MINIATURIZED DEVICES FOR COMBINED OPTICAL POWER CONVERSION AND DATA TRANSMISSION” and filed Sep. 29, 2015, in the United States Patent and Trademark Office, the disclosure of which is incorporated by reference herein in its entirety.

### RELATED APPLICATIONS

This application is related to U.S. patent application Ser. No. 14/683,498, entitled “MULTI-JUNCTION POWER CONVERTER WITH PHOTON RECYCLING” filed Apr. 10, 2015, and U.S. Provisional Patent Application Ser. No. 62/234,305 entitled “MULTI-JUNCTION PHOTOVOLTAIC MICRO-CELL ARCHITECTURES FOR ENERGY HARVESTING AND/OR LASER POWER CONVERSION,” filed Sep. 29, 2015, in the United States Patent and Trademark Office, the disclosures of which are incorporated by reference herein in its entirety.

### FIELD

The present disclosure relates to power conversion and data transmission devices and devices incorporating the same.

### BACKGROUND

Optical power transmission may be used to replace copper wiring, for example, for applications where conventional power supply is challenging or even impossible due to risk of short circuits and sparks, need for lightning protection, electromagnetic interference, need for galvanic isolation, high magnetic fields, heavy weight of long distance cabling, and/or susceptibility to corrosion and moisture. A light source, such as a laser or an LED, generates monochromatic light. At the receiver, a photovoltaic cell converts the monochromatic light back into electricity. Photovoltaic cells can convert monochromatic light into electricity more efficiently than the spectrum of solar radiation. By tuning the photovoltaic cell's semiconductor bandgap to the specific wavelength of the light, thermalization and transmission losses can be reduced or minimized. In this way, high conversion efficiencies of light into electricity over 50% can be realized.

Power can be transmitted in the form of light through an optical fiber, or directly through air. For example, power-over-fiber (PoF) is a technology in which a fiber optic cable carries optical power, which allows a device to be remotely powered while providing electrical isolation between the device and the power supply. In addition, the replacement of copper wire by optical fiber may enable the combination of power and data transmission into a single fiber.

### SUMMARY

Embodiments of the present disclosure may be applied in a number of overlapping specific fields, including but not limited to laser power conversion, optical data transfer, wearable devices, Internet of Things (IoT), and implantable devices.

According to some embodiments of the present disclosure, an optical data communication and power converter device includes a receiver circuit comprising an optical receiver. The optical receiver includes a photovoltaic device and a photoconductive device arranged within an area that is configured for illumination by a modulated optical signal emitted from a monochromatic light source of a transmitter circuit. The photovoltaic device is configured to generate electric current responsive to the illumination of the area by the modulated optical signal. The photoconductive device is configured to generate a data signal, distinct from the electric current, responsive to the illumination of the area by the modulated optical signal. A reverse bias voltage may be applied to the photoconductive device by the photovoltaic device, independent of an external voltage source.

In some embodiments, the photovoltaic device may be at least one photovoltaic cell (such as a transfer-printed photovoltaic cell having a surface area of about 4 square millimeters or less), and the photoconductive device may be a high bandwidth photodiode that is further configured to generate the data signal in response to application of a reverse bias voltage thereto.

In some embodiments, the at least one photovoltaic cell may be configured to apply the reverse bias voltage to the high bandwidth photodiode responsive to the illumination of the area by the modulated optical signal and independent of an external voltage source.

In some embodiments, the modulated optical signal may be a first optical signal, and the receiver circuit may be further configured to emit a second optical signal comprising light of a different wavelength than that of the first optical signal.

In some embodiments, the data signal may be a first data signal, and the transmitter circuit may further include a transmitter-side optical receiver that is configured to generate a second data signal responsive to illumination by the second optical signal emitted from the receiver circuit.

In some embodiments, the at least one photovoltaic cell of the optical receiver of the receiver circuit may be configured to be forward biased to emit the second optical signal. Additionally or alternatively, the receiver circuit may further include a receiver-side light source configured to emit the second optical signal. The at least one photovoltaic cell of the optical receiver may be stacked below or behind the receiver-side light source relative to a direction of the illumination by the first optical signal.

In some embodiments, the transmitter circuit may further include a driving circuit configured to operate the monochromatic light source such that the monochromatic light source emits the first optical signal. The first optical signal may have a wavelength that is longer than that of the second optical signal. The monochromatic light source may be stacked below or behind the transmitter-side optical receiver relative to a direction of the illumination by the second optical signal.

In some embodiments, the receiver-side light source may include a semiconductor material having a bandgap configured to emit light having the wavelength of the second optical signal and transmit light having the wavelength of the first optical signal therethrough, and the transmitter-side optical receiver may include a semiconductor material having a bandgap configured to absorb light having the wavelength of the second optical signal and transmit light having the wavelength of the first optical signal therethrough.

In some embodiments, a receiver housing may include a waterproof enclosure having the receiver circuit sealed therein. The receiver housing may include a transparent window therein that is configured to expose the area of the optical receiver to the illumination by the modulated optical signal. The receiver housing may be configured to provide a mechanical connection to a transmitter housing including a waterproof enclosure having the transmitter circuit and the monochromatic light source sealed therein. The transmitter housing may include a transparent window that is configured to permit the modulated optical signal to pass therethrough. As such, the device can be configured to provide power transfer and data transfer based on the mechanical connection and independent of an electrical connection between the transmitter and receiver housings.

In some embodiments, the transmitter circuit and/or the receiver circuit may be mounted on a respective submount. The submount may include a material that is transparent to the wavelengths of the first and/or second optical signals.

In some embodiments, the transmitter circuit and/or the receiver circuit are mounted on a respective submount. The submount may include a high-thermal conductivity material including silicon nitride, silicon carbide, aluminum nitride, diamond, silicon, or sapphire.

In some embodiments, the light source, the at least one photovoltaic cell, and/or the high bandwidth photodiode may be transfer-printed onto a surface of a respective submount, for example, using a same stamp or transfer element.

In some embodiments, the high bandwidth photodiode and the at least one photovoltaic cell may occupy a common footprint within the area of the optical receiver. Less than about 10 percent of the illumination by the modulated optical signal may be incident on the high bandwidth photodiode.

In some embodiments, the high bandwidth photodiode may have a light-receiving surface area of less than about 10 percent of that of the at least one photovoltaic cell.

In some embodiments, the high bandwidth photodiode may be on a surface of the at least one photovoltaic cell, or the at least one photovoltaic cell may include a window or notch therein that is configured to expose the high bandwidth photodiode to the illumination by the modulated optical signal.

In some embodiments, the area of the optical receiver including the high bandwidth photodiode and the at least one photovoltaic cell may be less than about 0.5 square millimeters.

In some embodiments, the monochromatic light source may include an array of surface emitting lasers configured to collectively emit the modulated optical signal, and the optical receiver may include an array of photovoltaic cells arranged within the area of the optical receiver in a manner corresponding to the surface emitting lasers. For example, the mohochromatic light source may include one or more vertical cavity surface emitting lasers. The surface emitting lasers may have a pitch corresponding to that of the photovoltaic cells. A number of the surface emitting lasers may or may not be equal to a number of the photovoltaic cells.

In some embodiments, the modulated optical signal may be amplitude modulated by operating the monochromatic light source to vary the intensity of the optical signal.

In some embodiments, the modulated optical signal may be frequency or polarization modulated by altering the wavelength or polarization of the output of the monochromatic light source, respectively. The high bandwidth photodiode may include a polarizer thereon that is configured to allow the modulated optical signal to pass therethrough to illuminate the high bandwidth photodiode.

In some embodiments, the modulated optical signal may be frequency modulated by altering a wavelength of the output of the monochromatic light source. The high bandwidth photodiode may include an optical filter thereon that is configured to allow the modulated optical signal to pass therethrough to illuminate the high bandwidth photodiode.

In some embodiments, the at least one photovoltaic cell may be a plurality of photovoltaic cells that are stacked to collectively provide a voltage that is greater than a photon energy of the illumination by the modulated optical signal that is incident on one of the photovoltaic cells in the stack.

According to further embodiments, an optical data and power transfer device includes a receiver circuit having photovoltaic cells and at least one photoconductive diode assembled within an area of the receiver circuit that is configured to receive incident illumination that is output from a transmitter circuit. The photovoltaic cells are electrically connected to the at least one photoconductive diode and are configured to provide a reverse bias voltage thereto responsive to the incident illumination.

In some embodiments, the incident illumination may include a modulated optical signal. The photovoltaic cells may be configured to generate electrical current in response to the incident illumination, and the at least one photoconductive diode may be configured to generate a data signal distinct from the electric current in response to the incident illumination.

In some embodiments, the photovoltaic cells may be sealed within a waterproof enclosure and are configured to receive the incident illumination through a transparent window therein.

In some embodiments, the area of the receiver circuit may have a surface area of less than about 0.5 mm².

In some embodiments, the receiver circuit may further include a device that is configured to transmit data to the transmitter circuit, allowing for bi-directional data transfer.

Other devices and/or methods according to some embodiments will become apparent to one with skill in the art upon review of the following drawings and detailed description. It is intended that all such additional embodiments, in addition to any and all combinations of the embodiments described herein, be included within this description, be within the scope of the invention, and be protected by the accompanying claims.

### BRIEF DESCRIPTION OF THE DRAWINGS

FIG. 1 is a block diagram illustrating a transmitter/receiver circuit for optical power and data transmission in accordance with some embodiments of the present disclosure.

FIG. 2 is a circuit diagram illustrating an example transmitter/receiver circuit for optical power and data transmission in accordance with some embodiments of the present disclosure in greater detail.

FIG. 3 is a circuit diagram illustrating an example transmitter-side circuit for optical power and data transmission in accordance with some embodiments of the present disclosure.

FIG. 4 is a circuit diagram illustrating an example receiver-side circuit for optical power and data reception in accordance with some embodiments of the present disclosure.

FIGS. 5A and 5B are block diagrams illustrating transmitter/receiver configurations for bi-directional power and data transmission in accordance with some embodiments of the present disclosure.

FIGS. 6A-6D illustrate examples of an optical receiver including a photovoltaic cell that can convert incident light from the transmitter into electrical power and further includes a photoconductive diode, for example a high bandwidth p-i-n photodiode, in accordance with some embodiments of the present disclosure.

FIG. 7 is a plan view illustrating an example array of photovoltaic cells and high bandwidth photodiodes in accordance with some embodiments of the present disclosure.

FIG. 8 is a circuit diagram illustrating an example optical receiver in which the photovoltaic cells are configured to provide a reverse bias voltage to the high bandwidth photodiodes in accordance with some embodiments of the present disclosure.

### DETAILED DESCRIPTION OF EMBODIMENTS

Embodiments of the present disclosure provide devices with combined data and power, using connections that are smaller and/or more robust than some conventional connections. For example, in contrast to some electrically-coupled connections, the connections of embodiments of the present disclosure may be optomechanical, and can accomplish power transfer and data transfer with a single point of connection (for example, an optical window), whereas electrical connections can require at least two points of contact. In addition, in contrast to some inductively-coupled connections, connections provided by embodiments of the present disclosure can be more miniaturizable. For example, connection components according to some embodiments may have a plan-view area of less than 0.5 square millimeters (mm²). Embodiments of the present disclosure can thus allow for connector reduction or elimination for devices. Embodiments of the present disclosure can also enable waterproof data and power coupling from one device to another.

Some embodiments of the present disclosure may include a first portion (transmitter) that includes at least one optical source (for example, a laser or LED) that is operable to generate modulated light, and a second portion (receiver) that includes one or more optical receivers that are operable to convert incident illumination or optical power into electrical energy, and also to receive optical data from the source and generate a data signal therefrom.

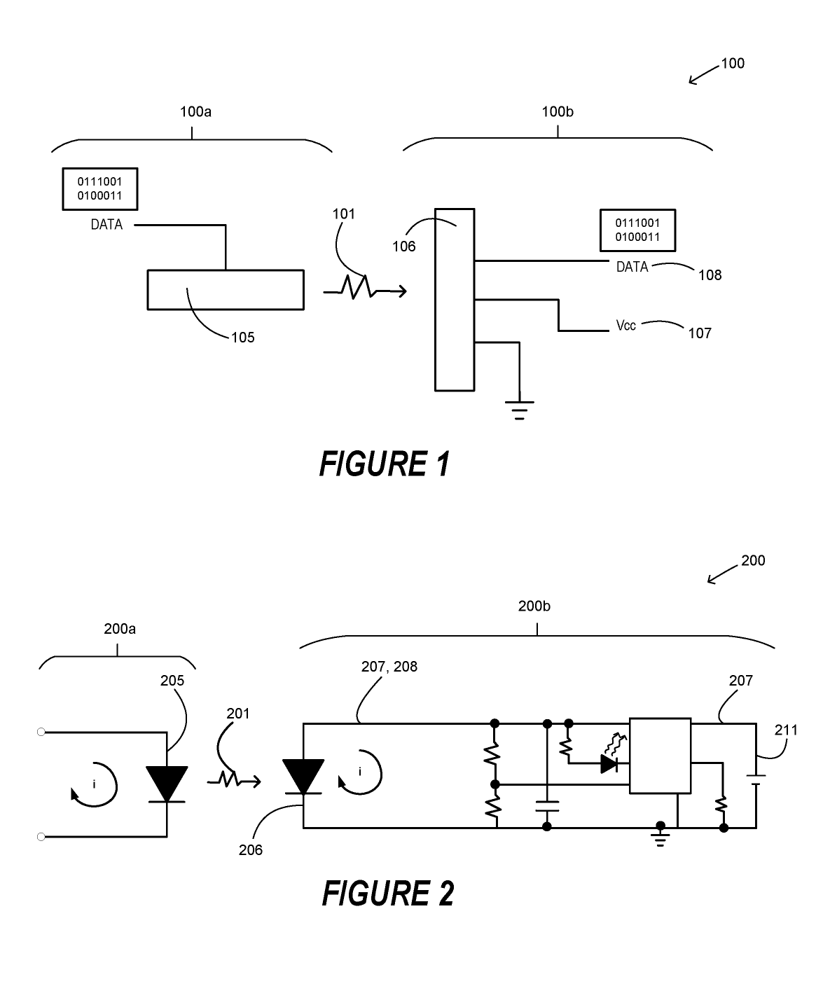

FIG. 1 is a block diagram illustrating a transmitter/receiver circuit for optical power and data transmission in accordance with some embodiments of the present disclosure. As shown in FIG. 1, an optical data communication and power converter device 100 includes a transmitter circuit 100a and a receiver circuit 100b. The transmitter circuit 100a includes a monochromatic light source 105, such as a light emitting diode (LED) or laser, and related circuitry that are configured to generate an optical signal including modulated light (also referred to herein as a modulated optical signal) 101. The modulated optical signal 101 provides for transmission of both power (based on the monochromatic light generated by the monochromatic light source 105) and data (based on modulation of the monochromatic light). Any of a number of modulation schemes, such as amplitude and/or frequency modulation, may be used to operate the light source 105 and/or the light emitted thereby to generate the optical signal including the modulated light 101.

Still referring to FIG. 1, the receiver circuit 100b includes an optical receiver 106 that is configured to generate respective signals 107 and 108 corresponding to electricity and data in response to illumination by the modulated optical signal 101 that is received from the transmitter circuit 100a. In some embodiments described herein, the optical receiver 106 includes a first, photovoltaic device (for example, one or more micro-transfer printed photovoltaic cells having respective surface areas of about 4 mm² or less) that is operable to generate electric current signal 107 responsive to the illumination by the modulated optical signal 101, and a second, photoconductive device (for example, a high-bandwidth photodiode) that is configured to generate a data signal 108 responsive to the illumination by the modulated optical signal 101. The data signal 108 and the electric current signal 107 are thus distinct electrical signals that are generated responsive to receipt of the same modulated optical signal 101.

FIG. 2 is a circuit diagram illustrating an example transmitter/receiver circuit 200 for optical power and data transmission in accordance with some embodiments of the present disclosure in greater detail. As shown in FIG. 2, an optical data communication and power converter device 200 includes a transmitter circuit 200a and a receiver circuit 200b. The transmitter circuit 200a includes a laser light source 205 and related circuitry that are configured to generate an optical signal including modulated monochromatic light 201, for transmission of both power (based on the monochromatic light generated by the monochromatic light source 205) and data (based on modulation of the monochromatic light). The receiver circuit 200b includes an optical receiver 206 that is configured to generate respective power and data signals in response to illumination by the modulated optical signal 201 that is received from the transmitter circuit 200a. FIG. 2 further illustrates an example charging circuit 209 coupled to the optical receiver 206. The charging circuit 209 is configured to provide the generated electric current 207 to a battery 211, such as a lithium ion battery used in portable consumer electronic devices.

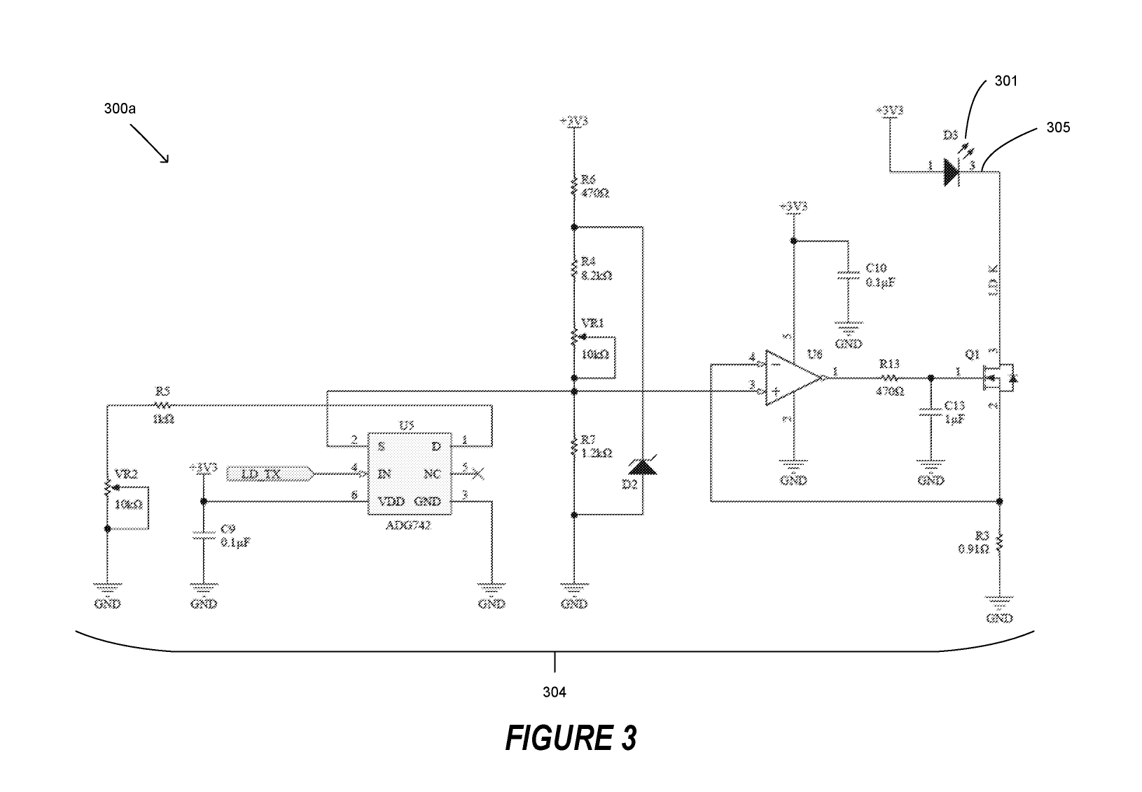

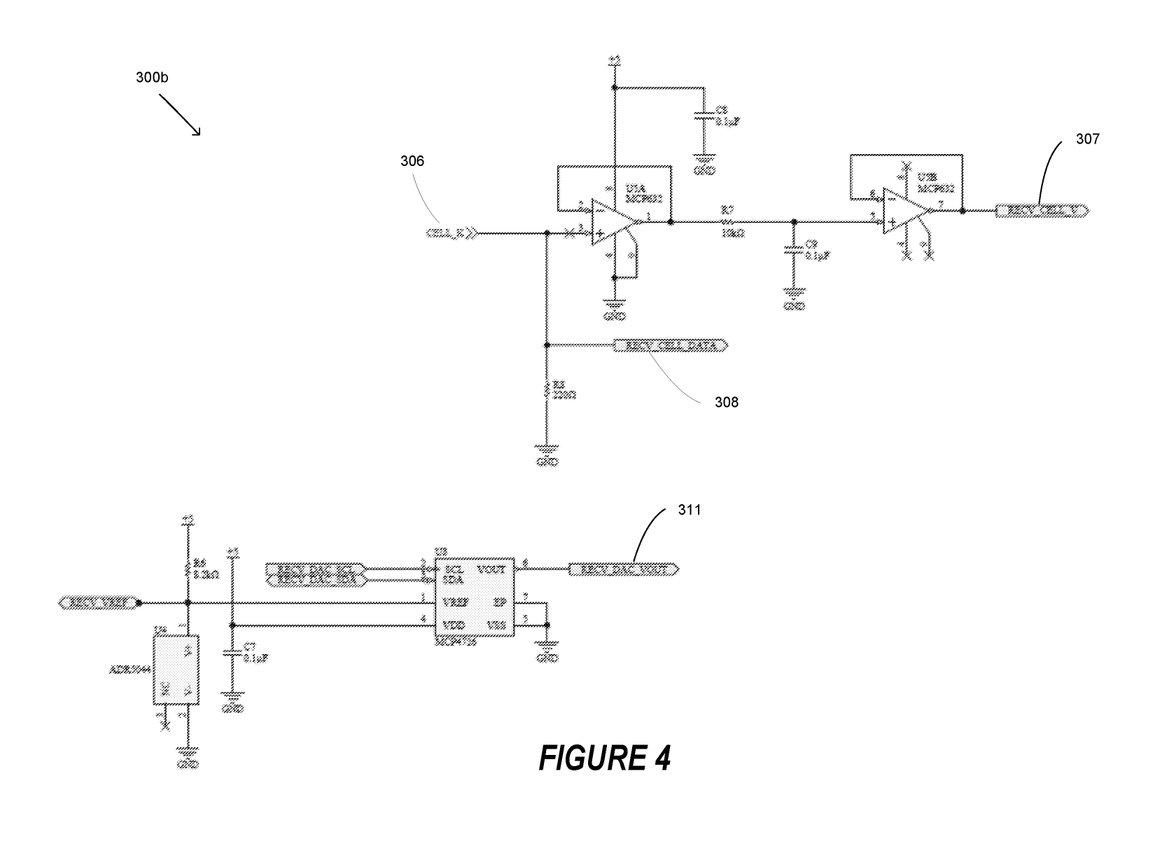

FIGS. 3 and 4 are circuit diagrams illustrating example implementations of a transmitter circuit 300a and a receiver circuit 300b for optical power and data transmission and reception, respectively, in accordance with some embodiments of the present disclosure. As shown in FIG. 3, the transmitter circuit 300a includes a driving circuit 304 coupled to a monochromatic light source 305, illustrated as a laser diode. The driving circuit 304 includes a combination of passive and active electrical components configured to operate the monochromatic light source 305 to emit an optical signal including modulated monochromatic light 301, using one or more of a number of modulation schemes (e.g., frequency modulation, amplitude modulation, etc.).

As shown in FIG. 4, the receiver circuit 300b includes an input 306 that is coupled to an optical receiver to receive a signal generated thereby in response to illumination by the modulated optical signal 301. The signal generated by the optical receiver includes an electrical current component 307 and a data component 308. For example, as described in greater detail herein, the optical receiver may include one or more photovoltaic cells that are configured to generate the electrical current signal 307, and one or more high bandwidth photodiodes (such as a p-i-n diode) that are configured to generate the data signal 308. The receiver circuit 300b further includes a combination of passive and active electrical components configured to provide the electrical current signal 307 for output 311 (for example, to a battery of a portable electronic device for charging), and to provide the data signal 308 for output (for example, to a signal processor for decoding).

The monochromatic light source of the transmitter circuit and/or the optical receiver of the receiver circuit of the optical data communication and power converter devices described herein may be assembled using micro-transfer printing techniques. For example, the monochromatic light source 105, 205, 305 may be a vertical cavity surface emitting laser, which can emit light from the top of a submount or through a transparent submount. The vertical cavity surface emitting laser may be transfer-printed on the submount in some embodiments. As such, the transmitter circuit may be economically advantaged because the die size may be miniaturized to a greater extent than some conventional transmitter circuits that use diced and wire bonded laser chips. For example, the semiconductor structures of the transfer printed lasers may be reduced in area by two or more orders of magnitude or more relative to those of some conventional lasers (the area of which may be difficult or impossible to reduce below about 150 μm×150 μm square for the sake of assembling them into packaged devices). Interconnecting the transfer printed lasers by thin-film interconnections allows for yet further miniaturization.

In the embodiments of FIGS. 1-4, the transmitter circuit 100a, 200a, 300a can be included in a transmitter housing, and the receiver circuit 100b, 200b, 300b can be included in a receiver housing that is separate from the transmitter housing. The transmitter housing and the receiver housing may be matably adapted by one or more mechanical and/or magnetic features that are configured to provide a mechanical connection therebetween. As such, the optical data communication and power converter devices 100, 200, 300 may be configured to provide power transfer and data transfer based on mechanical and optical coupling at a single point of connection, and independent of electrical contacts or connections between the transmitter and receiver housings. Such opto-mechanical coupling may allow for the elimination of one or more electrical ports, which may be particularly advantageous in portable consumer electronic devices where miniaturization and/or moisture-resistance may be of greater importance. For example, the transmitter housing and the receiver housing may define portions of an optical charger apparatus, for example, for use in charging a portable consumer electronic device. In such applications, the receiver circuit and/or the transmitter circuit can be sealed within respective waterproof housings or enclosures including transparent windows therein for optical charging, as no electrical contacts would be required.

In applications where the transmitter housing and the receiver housing define portions of an optical charger apparatus, the modulated optical signal 101, 201, 301 generated by the monochromatic light source 105, 205, 305 may be used for communication between the device charger 100a, 200a, 300a and the device receiver 100b, 200b, 300b. For instance, the device charger 100a, 200a, 300a may operate the monochromatic light source 105, 205, 305 to emit the modulated optical signal 101, 201, 301 as an indicator that the device charger 100a, 200a, 300a is properly aligned and ready to initiate charging with the device receiver 100b, 200b, 300b. Receipt of the modulated optical signal 101, 201, 301 by the device receiver 100b, 200b, 300b (and/or a device including or coupled to the device receiver 100b, 200b, 300b) may thus confirm that a proper mechanical connection has been established between the device charger 100a, 200a, 300a and the device receiver 100b, 200b, 300b.

In some embodiments, the device receiver 100b, 200b, 300b (and/or a device including or coupled to the device receiver 100b, 200b, 300b) may be further configured to provide a feedback signal to the device charger 100a, 200a, 300a, for example, to provide confirmation that a proper mechanical connection has been established. In particular, the data signal 108, 208, 308 generated by the optical receiver 106, 206, 306 may indicate to the device receiver 100b, 200b, 300b that the device charger 100a, 200a, 300a is properly aligned, and the device receiver 100b, 200b, 300b (or device coupled thereto) may include a device configured to transmit a confirmation signal back to the portable device charger 100a, 200a, 300a upon receipt of the modulated optical signal 101, 201, 301. Examples of devices that may configured to transmit such a confirmation signal may include a reflective surface or mirror (for example, a MEMS mirror that is operable responsive to the modulated optical signal 101, 201, 301), a receiver-side light source (for example, a laser or LED), or forward biasing of the existing optical receiver 106, 206, 306 to emit light that is detectable by a device included in the portable device charger 100a, 200a, 300a. Such features may be included in the receiver housing in some embodiments. As such, embodiments of the present disclosure may further allow for bi-directional data communication (and/or bi-directional power transfer) between the transmitter circuit 100a, 200a, 300a and the receiver circuit 100b, 200b, 300b.

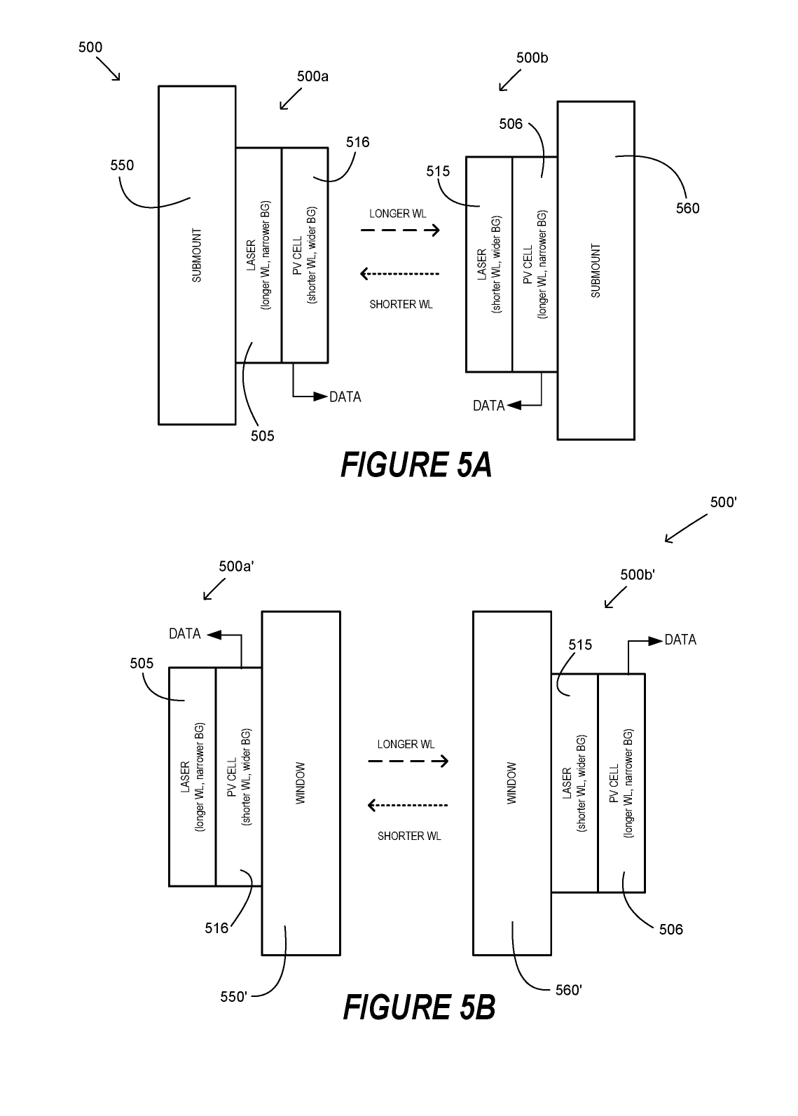

FIGS. 5A and 5B are block diagrams illustrating further embodiments of the present disclosure including transmitter/receiver configurations for bi-directional power and data transmission, without the use of wavelength splitting features. In particular, FIGS. 5A and 5B illustrate transmitter/receiver optical data communication and power converter devices 500 and 500′, respectively, in which the transmitter 500a and 500a′ further includes a device that can receive data, and the receiver 500b and 500b′ includes a device that can transmit data, such that the data transfer is bi-directional. As shown in FIGS. 5A and 5B, the transmitter 500a and 500a′ includes a first light source 505 (e.g., an LED or laser light source) that emits light with a longer wavelength than a second light source 515 (e.g., an LED or laser light source) included in the receiver 500b and 500b′. For example, the transmitter-side first light source 505 may be formed of a narrower-bandgap semiconductor material than the receiver-side second light source 515. The first light source 505 may be formed or otherwise provided underneath a first photovoltaic cell 516 in the transmitter 500a and 500a′.

Still referring to FIGS. 5A and 5B, the receiver 500b and 500b′ includes a second photovoltaic cell 506 that is configured to absorb the longer wavelength light emitted from the first light source 505. The second photovoltaic cell 506 may be formed or otherwise provided underneath the second light source 515 that emits the shorter wavelength light configured for absorption by the first photovoltaic cell 516 in the transmitter 500a and 500a′. The receiver-side second light source 515 is transparent to or otherwise configured to allow the longer wavelength light emitted by the transmitter-side first light source 505 to pass therethrough to the receiver-side second photovoltaic cell 506. The transmitter-side first photovoltaic cell 516 is configured to absorb the shorter wavelength light emitted by the second light source 515 in the receiver 500b and 500b′, but is transparent to or otherwise configured to allow the longer wavelength light emitted by the transmitter-side first light source 505 to pass therethrough. For example, the transmitter-side first photovoltaic cell 516 may be formed of a wider-bandgap semiconductor material than the receiver-side second photovoltaic cell 506. As such, based on the selection of material bandgaps and emission wavelengths of the components 505, 506, 515, and 516, a wavelength splitter may not be needed in some embodiments described herein.

In FIG. 5A, the transmitter-side components 516 and 505 are assembled or otherwise provided on a submount 550, while the receiver-side components 515 and 506 are assembled or otherwise provided on a submount 560. The submounts 550 and 560 are arranged in FIG. 5A so as not to obstruct optical signal transmission between the transmitter 500a and the receiver 500b. In contrast, in FIG. 5B, the transmitter-side components 516 and 505 are assembled or otherwise provided on a transparent submount 550′, while the receiver-side components 515 and 506 are assembled or otherwise provided on a transparent submount 560′. The submounts 550′ and 560′ are formed from materials that are transparent to the wavelengths of the optical signals transmitted between the transmitter 500a′ and the receiver 500b′, and thus, can be arranged therebetween, such that the optical signals pass through the transparent submounts 550′ and 560′. In some embodiments, the submounts 550, 550′, 560, and/or 560′ may include a high thermal conductivity substrate, for example silicon nitride, silicon carbide, aluminum nitride, diamond, silicon, and/or sapphire.

Although illustrated in FIGS. 5A and 5B with reference to particular structures for bi-directional data and/or power transmission, it will be understood that embodiments of the present disclosure are not limited thereto. For example, although illustrated with reference to embodiments 500 and 500′ including submounts 550/560 and 550′/560′ having particular characteristics, it will be understood that different combinations and arrangements of such submounts and structures thereon may be provided.

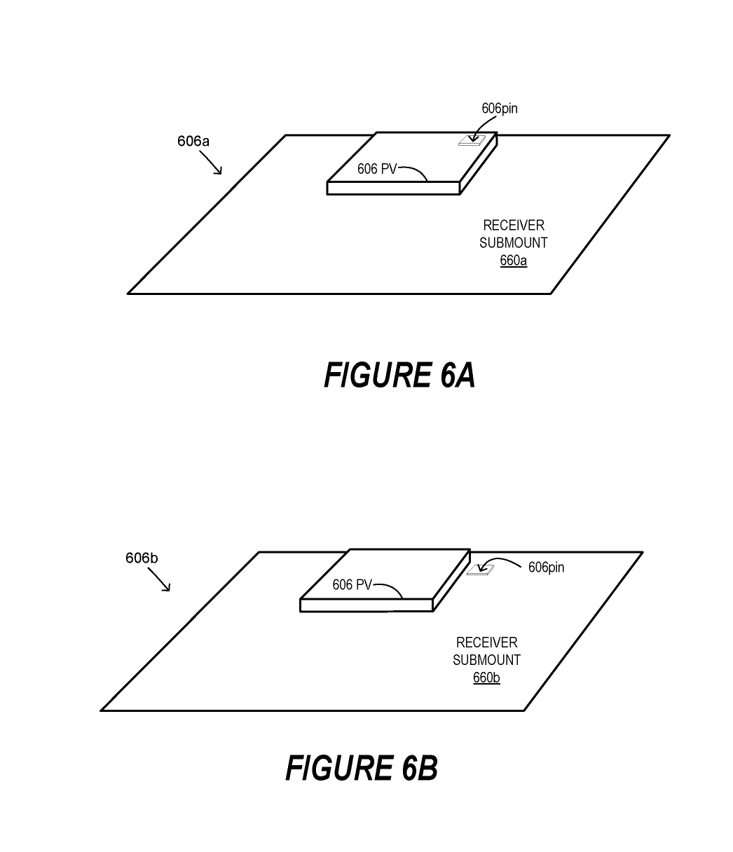

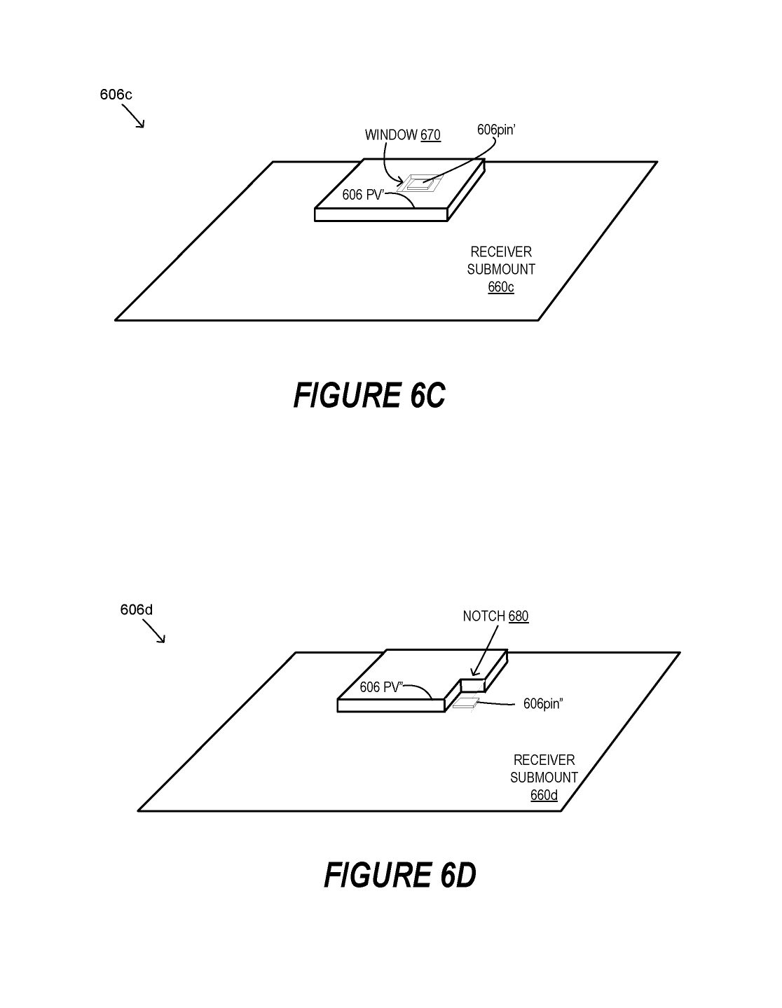

FIGS. 6A-6D illustrate embodiments of the present disclosure in which the receiver includes one or more photovoltaic cells configured to convert incident light from the transmitter into electrical power, in combination with one or more photoconductive devices, for example a high bandwidth (in terms of Gigabits per second (Gb/s); e.g., greater than about 1 Gb/s) photodiode such as a PIN diode having a (p-i-n) structure. Under reverse bias conditions, the high bandwidth photodiode is configured to detect the modulated optical signal from the transmitter and generate a data signal in response. In some embodiments as described in greater detail herein, the high bandwidth photodiode and the photovoltaic cell(s) may be electrically connected such that the photovoltaic cell(s) apply the reverse bias voltage to the high bandwidth photodiode in response to being illuminated by the modulated optical signal, so as to operate the high bandwidth photodiode as a photodetector that detects the modulation in the optical signal.

Placing the high bandwidth photodiode within the light-receiving area of the optical receiver submount may be less desirable from an efficiency perspective (as the presence of the high bandwidth photodiode may block or prevent some portion of the incident illumination from reaching the photovoltaic cell(s)), but may be advantageous in terms of occupying a smaller surface area or footprint (for example, in portable device charger applications). Despite references to specific receiver submounts, the embodiments illustrated in FIGS. 6A-6D may be implemented as photovoltaic cells in any of the optical data communication and power transfer devices described herein, such as the optical receivers 106, 206, 306, 506, and/or 516 of FIGS. 1-4 and 5A-5B.

In the embodiments of FIGS. 6A-6D the high bandwidth photodiode is illustrated as a PIN diode having a surface area of less than about 10% of the surface area of the photovoltaic (PV) cells, so as to reduce or avoid impinging on the surface area of the photovoltaic cells that is available for illumination. In particular, FIG. 6A illustrates an optical receiver 606a in which a PIN diode 606pin is placed, formed, or otherwise provided on top of the photovoltaic cell(s) 606pv.

FIG. 6B illustrates an optical receiver 606b in which the PIN diode 606pin is placed, formed, or otherwise provided on the receiver submount 660b in close proximity to the photovoltaic cell(s) 606pv thereon. In the arrangement of FIG. 6B, a greater fraction of the modulated optical signal emitted from the monochromatic light source (e.g., greater than about 50%) may be incident on the photovoltaic cell(s) 606pv, and a smaller fraction of the modulated optical signal (e.g., less than about 10%) may be incident on the PIN diode 606pin.

FIG. 6C illustrates an optical receiver 606c in which photovoltaic cells 606pv′ are placed, formed, or otherwise provided on a receiver submount 660c to define a window shape 670 within an internal area that is bounded the photovoltaic cells 606pv′. A PIN diode 606pin′ is placed, formed, or otherwise provided on the receiver submount 660c within the window-shaped area 670 defined by the photovoltaic cells 606pv′.

FIG. 6D illustrates an optical receiver 606d in which photovoltaic cells 606pv″ are placed, formed, or otherwise provided on a receiver submount 660d to define a notch shape 680 at an edge of the photovoltaic cell area. A PIN diode 606pin″ is placed, formed, or otherwise provided on the submount 660d adjacent the notch shape 680 defined by the photovoltaic cells 606pv″. Assembling the PIN diode 606pin′ or 606pin″ within the internal window shape 670 (FIG. 6C) or external notch shape 680 (FIG. 6D) may allow a smaller fraction (e.g., less than 10%) of the modulated optical signal from the transmitter to reach the PIN diode 606pin′ or 606pin″.

As shown in FIGS. 6A, 6C, and 6D, embodiments of the present disclosure allow for the integration of photovoltaic cells (for optical energy conversion) and high bandwidth photodiodes (for data reception) within a same or common area or footprint. Such a design may be of particular value in a portable device, for example, by allowing for reduction or minimization of surface area of a charging port.

In the examples of FIGS. 6A-6D, the high bandwidth photodiode 606pin, 606pin′, 606pin″ can be assembled on or adjacent the photovoltaic cell(s) 606pv, 606pv′, 606pv″ using micro-transfer printing techniques. The photovoltaic cell(s) 606pv, 606pv′, 606pv″ may likewise be assembled on the receiver submount 660a-660d using such micro-transfer printing techniques. The light sources 105, 205, 305, 505, 515 and/or the other optical receivers 106, 206, 306, 506, 516 described herein may also be assembled using micro-transfer printing techniques.

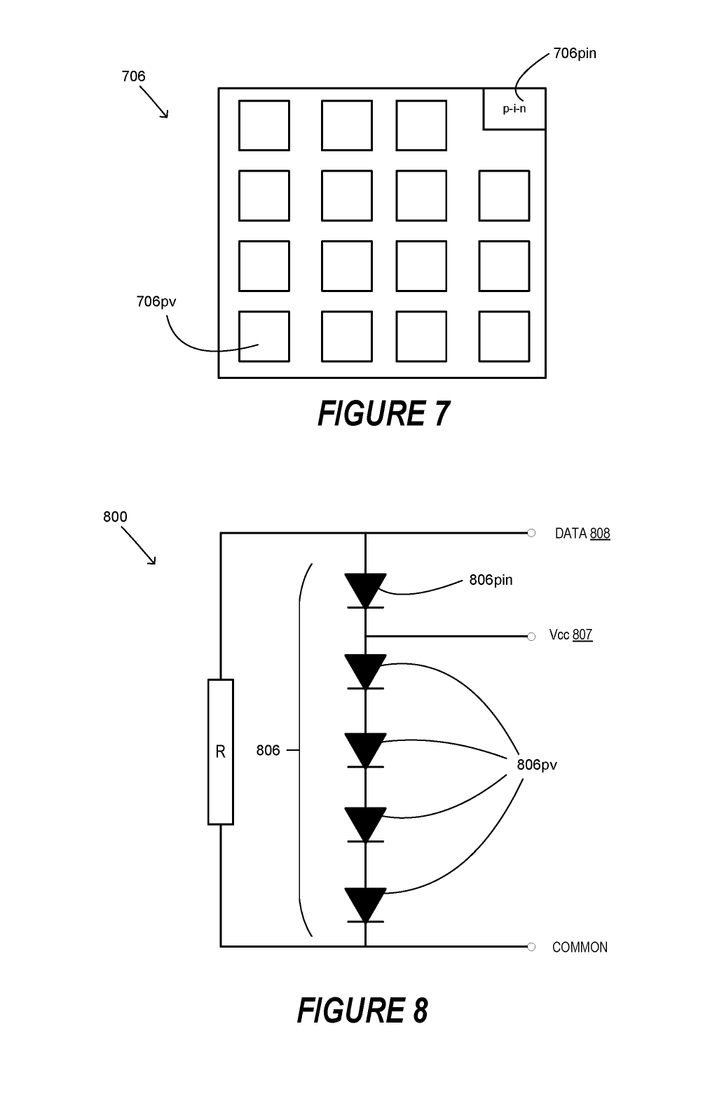

In some embodiments of the present disclosure, the optical receivers 106, 206, 306, 506, 516, 606a-606d described herein may be implemented by an array of photovoltaic cells and/or high bandwidth photodiodes in order to increase the bandwidth and/or power transfer capabilities. FIG. 7 is a plan view illustrating an example of an optical receiver array 706 including a plurality of photovoltaic cells 706pv and a PIN diode 706pin positioned at an edge or corner of the optical receiver array 706. The light sources 105, 205, 305, 505, 515 described herein may likewise be implemented by an array of laser diodes and/or LEDs that are spatially aligned with the array of photovoltaic cells and/or high bandwidth photodiodes, in a manner similar to the array shown in the example of FIG. 7.

For example, in some embodiments the light source 105, 205, 305, 505, 515 may include an array of vertical cavity surface emitting lasers having a spatial arrangement of several lasers on a first submount surface, and the corresponding optical receiver 106, 206, 306, 506, 516 may include an array of photovoltaic cells on a second submount surface having a spatial arrangement such that respective photovoltaic cells are aligned with respective lasers. In some embodiments, the array of lasers may be a regularly-spaced array having a fixed pitch or center-to-center distance between lasers of the array, and the array of photovoltaic cells may have the substantially same pitch. In some such embodiments, the number of lasers in the laser array may be equal to the number of photovoltaic cells in the photovoltaic cell array. In others such embodiments, the array of lasers may have a fixed pitch, the array of photovoltaic cells may have the substantially same pitch, but the number of lasers in the laser array may not be equal to the number of photovoltaic cells in the photovoltaic cell array. Also, as similarly discussed with reference to FIGS. 6A-6D, the array of photovoltaic cells may be formed or otherwise assembled by micro transfer printing onto a first submount using a stamp or other transfer element, and the array of lasers may be formed by micro transfer printing onto a second submount using the same or different stamp or transfer element.

As described above, the high bandwidth photodiodes are configured to detect modulated light emitted by the monochromatic light source in response to a reverse bias voltage applied thereto. For example, under reverse bias, a PIN diode does not ordinarily conduct; however, a current is generated when a photon of sufficient energy is incident on the PIN diode. In some embodiments, this reverse bias voltage may be provided by a power supply, for example, a battery of a portable consumer electronic device including an optical receiver having a PIN diode and PV cell combination integrated therein or otherwise coupled thereto. In further embodiments of the present disclosure, the photovoltaic cell(s) of the receiver circuit are electrically coupled so as to apply or otherwise provide the reverse bias voltage to the high bandwidth photodiode(s) in response to incident illumination. An example optical receiver 800 implementing this arrangement is schematically illustrated in FIG. 8.

As shown in FIG. 8, a plurality of photovoltaic cells 806pv are electrically connected in series with a PIN diode 806pin. In response to illumination by the modulated optical signal from the transmitter, the photovoltaic cells 806pv are not only configured to generate an electrical current 807 to provide power transmission to a device coupled thereto, but are also configured to reverse-bias the PIN diode 806pin. The reverse-biased PIN diode 806pin thus generates a data signal 808 responsive to excitation by the modulated optical signal. As such, the optical receiver 800 of FIG. 8 uses the incident modulated optical signal provided by the monochromatic light source of the transmitter to apply the reverse bias voltage for operation of the PIN diode 806pin to generate the data signal 808, such that a conventional power supply is not needed to reverse bias the PIN diode 806pin. Other active and/or passive components may also be included in the or coupled to the optical receiver 800 to provide the reverse bias voltage to the PIN diode 806pin.

The modulation scheme of the optical signal emitted by the light source may be amplitude modulation, frequency modulation, and/or polarization modulation. For example, amplitude modulation may be implemented by operating the light source to vary the intensity of the optical signal. Frequency or polarization modulation may be implemented by operating the light source to alter the wavelength or polarization of light emitted therefrom, respectively. In such embodiments, the high bandwidth photodiode(s) may include a corresponding optical filter (for example, a low-pass filter) and/or polarizer on a surface thereof having parameters selected to permit the incident illumination from the modulated light source.

In some embodiments, one or more of the photovoltaic cells described herein may be implemented as a multi-junction stack that is configured to generate electrical power with a voltage greater than the photon energy of the light produced by the transmitter, as described for example in U.S. patent application Ser. No. 14/683,498 filed Apr. 10, 2015, and U.S. Provisional Patent Application Ser. No. 62/234,305 filed Sep. 29, 2015, the disclosures of which are incorporated by reference herein in its entirety.

The present disclosure has been described above with reference to the accompanying drawings, in which embodiments are shown. However, this invention should not be construed as limited to the embodiments set forth herein. Rather, these embodiments are provided so that this disclosure will be thorough and complete, and will fully convey the scope of the present disclosure to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. In no event, however, should “on” or “directly on” be construed as requiring a layer to cover an underlying layer.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of embodiments of the present disclosure.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of herein is for the purpose of describing particular embodiments only and is not intended to be limiting of the present disclosure. As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, the regions illustrated in the figures are schematic in nature and their shapes are not intended to illustrate the actual shape of a region of a device and are not intended to limit the scope of the present disclosure.

Unless otherwise defined, all terms used in disclosing embodiments, including technical and scientific terms, have the same meaning as commonly understood by one of ordinary skill in the art to which this invention belongs, and are not necessarily limited to the specific definitions known at the time of the present disclosure. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entireties.

Aspects of the present disclosure are described herein with reference to flowchart illustrations and/or block diagrams of methods and systems according to embodiments. It is to be understood that the functions/acts noted in the blocks may occur out of the order noted in the operational illustrations. For example, two blocks shown in succession may in fact be executed substantially concurrently or the blocks may sometimes be executed in the reverse order, depending upon the functionality/acts involved.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

Although the present disclosure has been described herein with reference to various embodiments, it will be appreciated that further variations and modifications may be made within the scope and spirit of the principles of the present disclosure. While specific terms are employed, they are used in a generic and descriptive sense only and not for purposes of limitation, the scope of the present disclosure being set forth in the following claims.

That which is claimed:

1. An optical data communication and power converter device, comprising:
a receiver circuit comprising an optical receiver including a photovoltaic device and a photoconductive device arranged within an area that is configured for illumination by a modulated optical signal emitted from a monochromatic light source of a transmitter circuit,
wherein the photovoltaic device is configured to generate electric current responsive to the illumination of the area by the modulated optical signal, and
wherein the photoconductive device is configured to generate a data signal distinct from the electric current responsive to the illumination of the area by the modulated optical signal.

2. The device of claim 1, wherein the photovoltaic device comprises at least one photovoltaic cell having a surface area of about 4 square millimeters or less, and the photoconductive device comprises a high bandwidth photodiode that is further configured to generate the data signal in response to application of a reverse bias voltage thereto.

3. The device of claim 2, wherein the at least one photovoltaic cell is configured to apply the reverse bias voltage to the high bandwidth photodiode responsive to the illumination of the area by the modulated optical signal and independent of an external voltage source.

4. The device of claim 2, wherein the modulated optical signal is a first optical signal, and wherein the receiver circuit is further configured to emit a second optical signal comprising light of a different wavelength than that of the first optical signal.

5. The device of claim 4, wherein the optical receiver is a first optical receiver, wherein the data signal is a first data signal, and wherein the device further comprises:
the transmitter circuit comprising the monochromatic light source that is configured to emit the modulated optical signal, wherein the transmitter circuit further comprises:
a second optical receiver that is configured to generate a second data signal responsive to illumination by the second optical signal emitted from the receiver circuit.

6. The device of claim 5, wherein the monochromatic light source is a first light source, and wherein the receiver circuit further comprises:
a second light source configured to emit the second optical signal,
wherein the at least one photovoltaic cell of the first optical receiver is stacked behind the second light source relative to a direction of the illumination by the first optical signal.

7. The device of claim 6, wherein the transmitter circuit further comprises:
a driving circuit configured to operate the monochromatic light source such that the monochromatic light source emits the first optical signal, wherein the first optical signal has a wavelength that is longer than that of the second optical signal,
wherein the monochromatic light source is stacked behind the second optical receiver relative to a direction of the illumination by the second optical signal.

8. The device of claim 7, wherein:
the second light source comprises a semiconductor material having a bandgap configured to emit light having the wavelength of the second optical signal and transmit light having the wavelength of the first optical signal therethrough; and
the second optical receiver comprises a semiconductor material having a bandgap configured to absorb light having the wavelength of the second optical signal and transmit light having the wavelength of the first optical signal therethrough.

9. The device of claim 4, further comprising:
a receiver housing comprising a waterproof enclosure including the receiver circuit sealed therein,
wherein the receiver housing comprises a transparent window therein that is configured to expose the area of the optical receiver to the illumination by the modulated optical signal, and
wherein the receiver housing is configured to provide a mechanical connection to a transmitter housing comprising a waterproof enclosure including the transmitter circuit and the monochromatic light source sealed therein, the transmitter housing comprising a transparent window that is configured to permit the modulated optical signal to pass therethrough.

10. The device of claim 5, wherein the transmitter circuit and/or the receiver circuit are mounted on a respective submount comprising a material that is transparent to the wavelengths of the first and/or second optical signals.

11. The device of claim 5, wherein the transmitter circuit and/or the receiver circuit are mounted on a respective submount comprising a high-thermal conductivity material including silicon nitride, silicon carbide, aluminum nitride, diamond, silicon, or sapphire.

12. The device of claim 2, wherein the high bandwidth photodiode and the at least one photovoltaic cell occupy a common footprint within the area of the optical receiver, and wherein less than about 10 percent of the illumination by the modulated optical signal is incident on the high bandwidth photodiode.

13. The device of claim 12, wherein the high bandwidth photodiode has a light-receiving surface area of less than about 10 percent of that of the at least one photovoltaic cell.

14. The device of claim 13, wherein the high bandwidth photodiode is on a surface of the at least one photovoltaic cell, or wherein the at least one photovoltaic cell includes a window or notch therein that is configured to expose the high bandwidth photodiode to the illumination by the modulated optical signal.

15. The device of claim 12, wherein the area of the optical receiver including the high bandwidth photodiode and the at least one photovoltaic cell is less than about 0.5 square millimeters.

16. The device of claim 2, wherein the monochromatic light source comprises an array of surface emitting lasers configured to collectively emit the modulated optical signal, and wherein the optical receiver comprises an array of photovoltaic cells arranged within the area of the optical receiver in a manner corresponding to the surface emitting lasers.

17. The device of claim 1, wherein the at least one photovoltaic cell comprises a plurality of photovoltaic cells that are stacked to collectively provide a voltage that is greater than a photon energy of the illumination by the modulated optical signal that is incident on one of the photovoltaic cells in the stack.

18. An optical data and power transfer device, comprising:
a receiver circuit including photovoltaic cells and at least one photoconductive diode assembled within an area of the receiver circuit that is configured to receive incident illumination that is output from a transmitter circuit,
wherein the photovoltaic cells are electrically connected to the at least one photoconductive diode and are configured to provide a reverse bias voltage thereto responsive to the incident illumination.

19. The device of claim 18, wherein the incident illumination comprises a modulated optical signal, wherein the photovoltaic cells are configured to generate electrical current in response to the incident illumination, and wherein the at least one photoconductive diode is configured to generate a data signal distinct from the electric current in response to the incident illumination.

20. The device of claim 19, wherein:
the at least one photoconductive diode is on a surface of at least one of the photovoltaic cells, or the photovoltaic cells define a window or notch that is configured to expose the at least one photoconductive diode to the modulated optical signal; and
the area including the photovoltaic cells and the at least one photoconductive diode is less than about 0.5 square millimeters.
